(19) United States
(12) Patent Application Publication
(10) Pub. No.: US 2011/0177954 A1
(43) Pub. Date: Jul. 21, 2011

(54) SUPERCONDUCTING ELECTRICITY TRANSMISSION SYSTEM

(75) Inventors: Bruce Gamble, Wellesley, MA (US); David Madura, Ashland, MA (US); Peter Winn, Shrewsbury, MA (US); Jie Yuan, South Grafton, MA (US)

(73) Assignee: American Superconductor Corporation, Devens, MA (US)

(21) Appl. No.: 13/010,239

(22) Filed: Jan. 20, 2011

Related U.S. Application Data
(60) Provisional application No. 61/296,770, filed on Jan. 20, 2010.

(51) Int. Cl. H01L 39/02; H02M 7/02; H05K 7/20; H01L 39/18

(52) U.S. Cl. 505/163; 363/13; 361/699; 505/150

(57) ABSTRACT

The present disclosure generally relates to a superconducting power grid having one or more AC/DC converters. The superconducting grid may further include one or more pairs of superconducting DC cables connecting each AC/DC converter. Each pair of superconducting DC cables may include a first positive polarity cable and a first negative polarity cable. The grid may also include at least one switching device configured to operatively connect at least one of the first and second AC/DC converters with at least one of the pairs of superconducting DC cables, the switching device further configured to adjust the polarity of at least one of the polarity cables. Other embodiments and implementations are also within the scope of the present disclosure.

### CROSS-REFERENCE TO RELATED APPLICATION

This application claims the benefit of U.S. provisional patent application Ser. No. 61/296,770, filed on 20 Jan. 2010, the entire disclosure of which is incorporated herein by reference.

### TECHNICAL FIELD

This disclosure relates to electricity transmission systems and, more particularly, to an electricity transmission system including a cryogenic cooling system for high temperature superconductor (“HTS”) devices, such as HTS power cables.

### BACKGROUND

Superconductivity refers to a state of materials in which the electrical resistance becomes zero when the material is cooled to a sufficiently low temperature, referred to as the critical temperature. One type of superconductor, referred to as a high temperature superconductor (HTS), has a critical temperature in excess of the boiling point of liquid nitrogen of about 77K at atmospheric pressure.

The use of superconductive materials and, in particular, superconducting cables, is advantageous because of the elimination of resistive losses. As a result, superconducting cables are being designed, built and tested for use in industrial and utility applications, such as power transmission systems.

High temperature superconductors may be used to construct superconducting power cables, which are capable of serving very large power requirements at medium and high voltage ratings. To make a HTS cable operate properly, cryogenic cooling systems with circulating sub-cooled liquid nitrogen are often used to maintain the HTS cable in a superconducting state during normal operation.

Conventionally, cryogenic refrigeration systems are used to cool cold dielectric superconducting cables to a temperature (˜70K), which may be much lower than the HTS critical temperature (˜90K). This may allow the transmission at higher currents since the critical current increases dramatically with a decrease in the operating temperature. Such systems may contain a refrigeration unit, a circulating pump and a cooling loop for providing a refrigerant, or coolant, such as liquid nitrogen, at a temperature much lower than the critical temperature. The refrigeration unit is a mechanical refrigeration device that produces cooling power at cryogenic temperature. The coolant, e.g. liquid nitrogen, flows from the refrigeration unit into the cooling loop via a circulating pump. The coolant circulates through the cooling loop extracting heat from the HTS cable, and then returns to the refrigeration system for removal of the heat and circulates back to the cooling loop. The cooling loop could be a tube external to the superconducting cable assembly, a tube in which the coolant flows and in which the cable is also contained or the hollow center formed by the superconducting cable former.

In existing electrical grids, the most common method for supplying redundancy in a utility system is by including multiple parallel circuits. For example, a DC cable might operate in parallel with AC lines and the larger electricity grid. In this way, the loss of any one line would not impair the operation of the overall grid. In some cases, however, such as the case of a ring bus topology, the overall grid may not be capable of providing an alternate path for power flow. A redundant cable must be provided, which greatly adds to the cost of the overall system.

### SUMMARY OF DISCLOSURE

In an embodiment of the present disclosure a superconducting power grid is provided. The power grid may include a first AC/DC converter configured to receive a first alternating current having a first phase, a second AC/DC converter configured to receive a second alternating current having a second phase, and a third AC/DC converter configured to receive a third alternating current having a third phase. The power grid may further include a first pair of superconducting DC cables connecting the first AC/DC converter and the second AC/DC converter, the first pair of superconducting DC cables including a first positive polarity cable and a first negative polarity cable. The power grid may further include a second pair of superconducting DC cables connecting the second AC/DC converter and the third AC/DC converter, the second pair of superconducting DC cables including a second positive polarity cable and a second negative polarity cable. The power grid may also include a third pair of superconducting DC cables connecting the first AC/DC converter and the third AC/DC converter, the third pair of superconducting DC cables including a third positive polarity cable and a third negative polarity cable. The power grid may additionally include at least one switching device configured to operatively connect at least one of the first, second and third AC/DC converters with at least one of the pairs of superconducting DC cables, the switching device further configured to adjust the polarity of at least one of the polarity cables.

One or more of the following features may be included. The switching device may include an H-bridge. The power grid may further include at least one refrigeration unit configured to provide a cryogenic fluid to at least one of the superconducting DC cables. The cryogenic fluid may be liquid nitrogen.

In some embodiments, the power grid may further include at least one liquid nitrogen pump associated with the at least one refrigeration unit, the liquid nitrogen pump configured to alter a flow of liquid nitrogen through at least one of the superconducting DC cables. The power grid may also include a control system configured to re-route the cryogenic fluid if one or more of the at least one refrigeration unit is defective. The at least one refrigeration unit includes at least one heat exchanger operatively connected with a cryogenic refrigerator.

In another embodiment of the present disclosure, a superconducting power grid is provided. The power grid may include a first AC/DC converter configured to receive a first alternating current having a first phase, a second AC/DC converter configured to receive a second alternating current having a second phase, and a third AC/DC converter configured to receive a third alternating current having a third phase. The power grid may also include a first pair of superconducting DC cables connecting the first AC/DC converter and the second AC/DC converter, the first pair of superconducting DC cables including a first positive polarity cable and a first negative polarity cable. The power grid may additionally include a second pair of superconducting DC cables connecting the second AC/DC converter and the third AC/DC converter, the second pair of superconducting DC cables including a second positive polarity cable and a second negative polarity cable. The power grid may further include a third pair of superconducting DC cables connecting the first AC/DC converter and the third AC/DC converter, the third pair of superconducting DC cables including a third positive polarity cable and a third negative polarity cable. The power grid may further include at least one refrigeration unit configured to provide a cryogenic fluid to at least one of the superconducting DC cables. The power grid may also include a control system configured to control the flow of the cryogenic fluid through the superconducting DC cables, the control system configured to allow for the re-routing of the cryogenic fluid through the superconducting DC cables.

One or more of the following features may be included. The control system may be configured to re-route the cryogenic fluid if a refrigeration unit associated with any of the AC/DC converters is disabled. Each of the superconducting DC cables may include at least one high temperature superconducting (HTS) wire. Each of the superconducting DC cables may include a conduit configured to contain the cryogenic fluid. At least two of the first phase, second phase and third phases may be different.

In another embodiment of the present disclosure a method for providing redundancy in a superconducting power grid is provided. The method may include providing a first AC/DC converter configured to receive a first alternating current having a first phase, a second AC/DC converter configured to receive a second alternating current having a second phase, and a third AC/DC converter configured to receive a third alternating current having a third phase. The method may also include connecting, via a first pair of superconducting DC cables, the first AC/DC converter and the second AC/DC converter, the first pair of superconducting DC cables including a first positive polarity cable and a first negative polarity cable. The method may further include connecting, via a second pair of superconducting DC cables, the second AC/DC converter and the third AC/DC converter, the second pair of superconducting DC cables including a second positive polarity cable and a second negative polarity cable. The method may also include connecting, via a third pair of superconducting DC cables, the first AC/DC converter and the third AC/DC converter, the third pair of superconducting DC cables including a third positive polarity cable and a third negative polarity cable. The method may further include switching the polarity of at least one of the polarity cables via at least one switching device configured to operatively connect at least one of the first, second and third AC/DC converters with at least one of the pairs of superconducting DC cables.

In another embodiment of the present disclosure, a method for providing redundancy in a superconducting power grid is provided. The method may include providing a first AC/DC converter configured to receive a first alternating current having a first phase, a second AC/DC converter configured to receive a second alternating current having a second phase, and a third AC/DC converter configured to receive a third alternating current having a third phase. The method may further include connecting, via a first pair of superconducting DC cables, the first AC/DC converter and the second AC/DC converter, the first pair of superconducting DC cables including a first positive polarity cable and a first negative polarity cable. The method may also include connecting, via a second pair of superconducting DC cables, the second AC/DC converter and the third AC/DC converter, the second pair of superconducting DC cables including a second positive polarity cable and a second negative polarity cable. The method may further include connecting, via a third pair of superconducting DC cables, the first AC/DC converter and the third AC/DC converter, the third pair of superconducting DC cables including a third positive polarity cable and a third negative polarity cable. The method may additionally include providing a cryogenic fluid to at least one of the superconducting DC cables via at least one refrigeration unit, controlling the flow of the cryogenic fluid through the superconducting DC cables using a control system, and re-routing the cryogenic fluid through the superconducting DC cables using an alternative path.

In another embodiment of the present disclosure, a superconducting power grid is provided. The superconducting power grid may include a first AC/DC converter configured to receive a first alternating current having a first phase and a second AC/DC converter configured to receive a second alternating current having a second phase. The superconducting power grid may also include a first pair of superconducting DC cables connecting the first AC/DC converter and the second AC/DC converter, the first pair of superconducting DC cables including a first positive polarity cable and a first negative polarity cable. The superconducting power grid may further include a second pair of superconducting DC cables connecting the first AC/DC converter and the second AC/DC converter, the second pair of superconducting DC cables including a second positive polarity cable and a second negative polarity cable. The superconducting power grid may also include at least one switching device configured to operatively connect at least one of the first and second AC/DC converters with at least one of the pairs of superconducting DC cables, the switching device further configured to adjust the polarity of at least one of the polarity cables.

One or more of the following features may be included. At least one refrigeration unit may be associated with one or more of the superconducting cables. The at least one refrigeration unit may be configured to provide a cryogenic fluid to the one or more superconducting cables. The grid may include a control system configured to control the flow of the cryogenic fluid through the superconducting DC cables, the control system configured to allow for the re-routing of the cryogenic fluid through the superconducting DC cables. The at least one switching device may be an H-bridge. The control system may redirect the flow of coolant if one or more of the at least one refrigeration units is disabled.

The details of one or more implementations are set forth in the accompanying drawings and the description below. Other features and advantages will become apparent from the description, the drawings, and the claims.

### BRIEF DESCRIPTION OF THE DRAWINGS

FIG. 1 is a schematic diagram of a redundant superconducting electricity transmission system having a ring bus topology;

FIG. 2 is a schematic diagram a redundant superconducting electricity transmission system including a cooling system for HTS cable;

FIG. 3 is an isometric view of a single pole superconducting cable in a rigid cryostat;

FIG. 4 is an isometric view of a hollow-core HTS cable;

FIG. 5 is a schematic diagram of one embodiment of a redundant superconducting electricity transmission system depicting electrical cross connections;

FIG. 6 is a schematic diagram of one embodiment of a redundant superconducting electricity transmission system depicting the coolant loop valve configuration at one station;

FIG. 7 is a schematic diagram of one embodiment of the cooling system of a redundant superconducting electricity transmission system configured for normal operation;

FIG. 8 is a schematic diagram of one embodiment of the cooling system of a redundant superconducting electricity transmission system configured for operation with one refrigeration unit out of service; and

FIG. 9 is a flowchart depicting operations consistent with a method in accordance with one embodiment of the present disclosure.

### DETAILED DESCRIPTION OF THE PREFERRED EMBODIMENTS

Generally, the present disclosure is directed towards a redundant electricity transmission system. The embodiments described herein may be used to connect multiple AC grids, which may or may not be out-of-phase or at different frequencies. The present disclosure allows for two separate cables (i.e., one positive and one negative) between each of a number of AC/DC terminals, to limit the possibility of a pole to pole fault. The embodiments of the present disclosure may permit for the failure of any two of the cables while allowing the overall system to continue operation. The present disclosure also provides redundancy with regard to any potential failures in the cryogenic cooling system associated with the electricity transmission system.

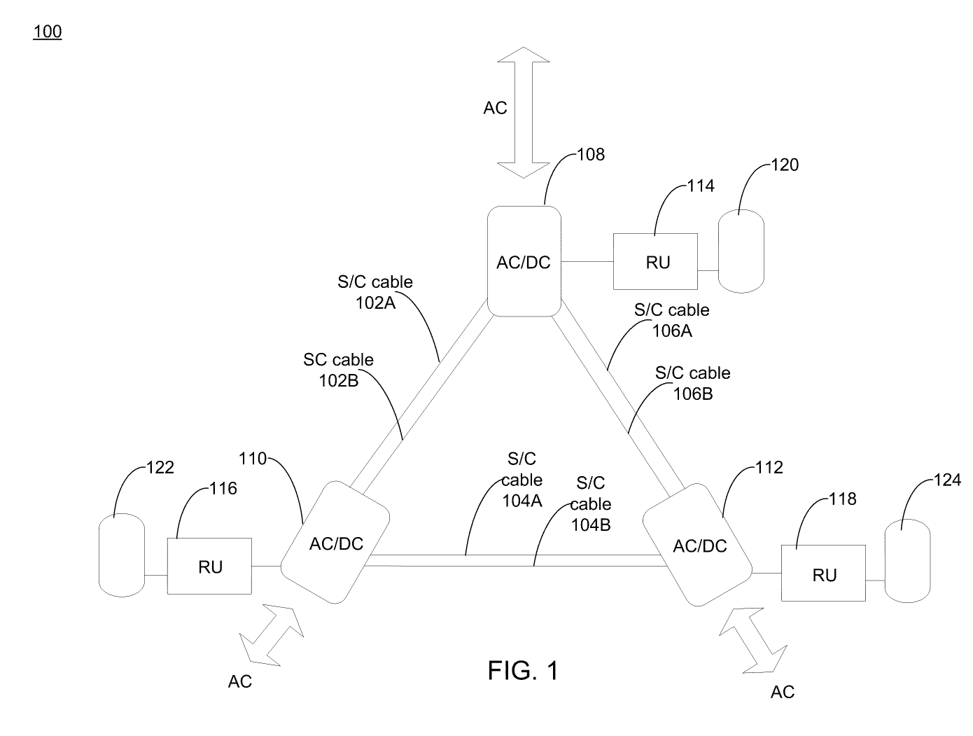

Referring to FIG. 1, a portion of a utility power grid 100 may include a high temperature superconductor (HTS) cable 102. In this particular embodiment, a DC cable system is provided depicting a two-pole (positive and negative) configuration. HTS cable 102 may be any length (e.g. 3 km) and may provide a relatively high current/low resistance electrical path for the delivery of electrical power from generation stations (not shown) or imported from remote utilities (not shown).

The cross-sectional area of HTS cable 102 may only be a fraction of the cross-sectional area of a conventional copper core cable and may be capable of carrying the same amount of electrical current or more. As discussed above, within the same cross-sectional area, an HTS cable may provide three to five times the current-carrying capacity of a conventional AC cable; and up to ten times the current-carrying capacity of a conventional DC cable. As HTS technology matures, these ratios may increase.

HTS cable 102 may include HTS wire, which may be capable of handling as much as one-hundred-fifty times the electrical current of similarly-sized copper wire or more. Accordingly, by using a relatively small quantity of HTS wire (as opposed to a large quantity of conventional conductors (e.g., copper and/or aluminum) stranded within the core of a traditional AC cable), an HTS power cable may be constructed that is capable of providing three to five times as much electrical power as an equivalently-sized traditional conductor power cable.

In some embodiments, superconducting power grid 100 may include one or more superconducting DC cables. For example, and as shown in FIG. 1, a first pair of superconducting DC cables 102A-B, a second pair of superconducting DC cables 104A-B, and a third pair of superconducting DC cables 106A-B are shown. First pair of superconducting DC cables 102A-B may be configured to connect first AC/DC converter 108 and second AC/DC converter 110. First pair of superconducting DC cables 102A-B may include a first positive polarity cable and a first negative polarity cable (e.g. DC cable 102A may have a positive polarity and DC cable 102B may have a negative polarity).

In some embodiments, second pair of superconducting DC cables 104A-B may be configured to connect second AC/DC converter 110 and third AC/DC converter 112. Second pair of superconducting DC cables 104A-B may also include a second positive polarity cable and a second negative polarity cable similar to that described above. Similarly, third pair of superconducting DC cables 106A-B may be configured to connect first AC/DC converter 108 and third AC/DC converter 112. Third pair of superconducting DC cables 106A-B may also include a positive polarity cable and a negative polarity cable as discussed above.

In some embodiments, each of AC/DC converters 108, 110, and 112 may be configured to receive alternating currents having a particular phase and frequency from other parts of a larger utility grid. For example, as way of example and not of limitation, AC/DC converter 108 may be configured to receive current from the Eastern Interconnection of the United States power grid, converter 110 may be configured to receive current from the Western Interconnection of the United States power grid, and converter 112 may be configured to receive current from the Texas Interconnection of the United States power grid.

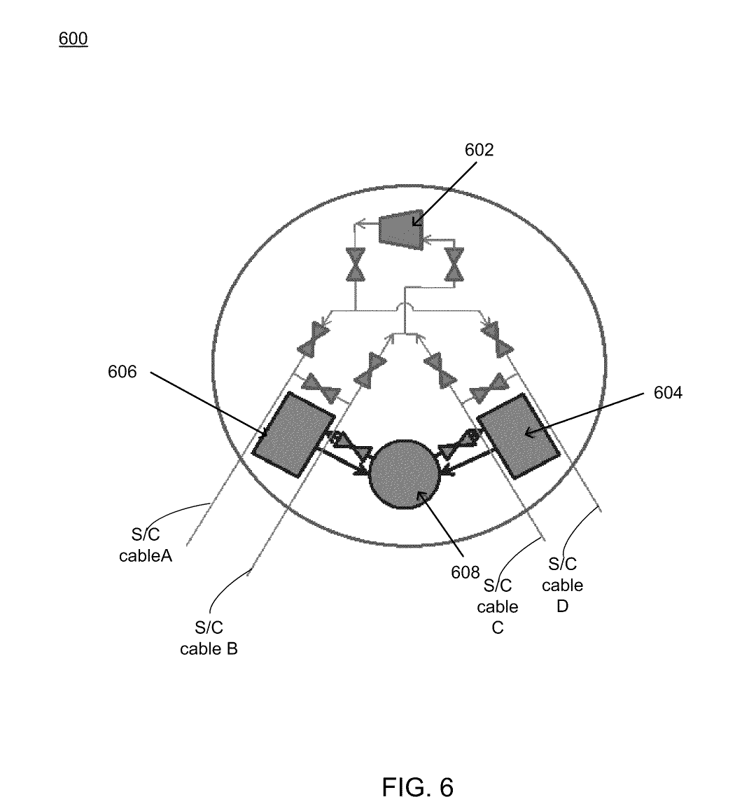

In some embodiments, each of AC/DC converters 108, 110, and 112 may be operatively connected with one or more refrigeration units, e.g., refrigeration units 114, 116, and 118, which may be configured to provide a cryogenic fluid to various portions of the power grid, including, but not limited to, superconducting DC cables 102, 104, and 106. One or more control systems may be provided, which may be configured to control the flow of the cryogenic fluid through the superconducting DC cables. For example, and as described in further detail below with reference to FIGS. 6-8, the control system may be configured to allow for the re-routing of the cryogenic fluid through various pathways associated with superconducting DC cables 102, 104, and 106. One or more cryogenic storage containers, e.g., 120, 122, and 124, may be connected to various components of the grid in order to provide cryogenic fluids, such as liquid nitrogen, cables 102, 104, 106 and other components as required.

In some embodiments of the present disclosure, the power grid may include a first AC/DC converter configured to receive a first set of 3 alternating currents having a first phase, a second AC/DC converter configured to receive a second set of 3 alternating currents having a second phase, and a third AC/DC converter configured to receive a third set of 3 alternating currents having a third phase. The power grid may also include a first pair of superconducting DC cables connecting the first AC/DC converter and the second AC/DC converter, the first pair of superconducting DC cables including a first positive polarity cable and a first negative polarity cable. The power grid may additionally include a second pair of superconducting DC cables connecting the second AC/DC converter and the third AC/DC converter, the second pair of superconducting DC cables including a second positive polarity cable and a second negative polarity cable. The power grid may further include a third pair of superconducting DC cables connecting the first AC/DC converter and the third AC/DC converter, the third pair of superconducting DC cables including a third positive polarity cable and a third negative polarity cable. The power grid may further include at least one refrigeration unit configured to provide a cryogenic fluid to at least one of the superconducting DC cables. The power grid may also include a control system configured to control the flow of the cryogenic fluid through the superconducting DC cables, the control system configured to allow for the re-routing of the cryogenic fluid through the superconducting DC cables.

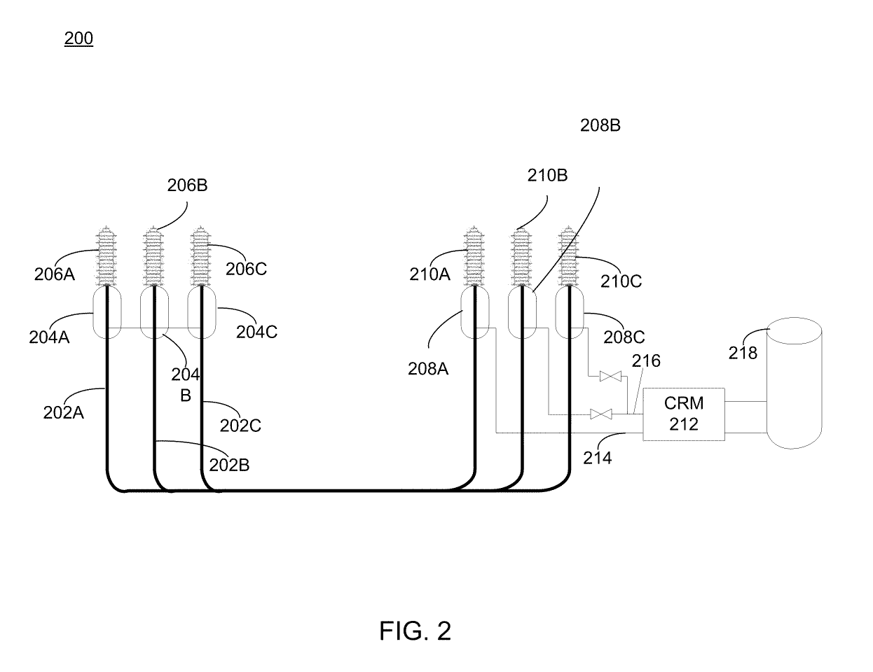

Referring now to FIG. 2, there is a shown one exemplary embodiment of a cooling system 200 consistent with an embodiment of the present disclosure. In this particular embodiment, cooling system 200 is shown in a 3-phase AC cable system. Cooling system 200 may include, for example, three separate HTS cables 202A, 202B, and 202C. Each HTS cable may include both a cold termination and a high voltage termination on each end of the cable. For example, HTS cable 202A may include cold termination 204A coupled with high voltage termination 206A on a first end of the cable, and cold termination 208A coupled with high voltage termination 210A on a second end of the cable. HTS cables 202B and 202C may include similar configurations, as depicted in FIG. 2. One example of a superconducting cable termination is described in Cryogenic Refrigeration System for HTS Cables by Ron C. Lee et al., IEEE Transactions on Applied Superconductivity, vol. 15, No. 2, June 2005, p. 1788. However, alternative termination designs may be employed as well.

Each of HTS cables 202A, 202B, and 202C may be connected with a cryogenic refrigeration module 212, which may be connected with each cable via supply line 214 and return line 216. Any number of lines may be employed. Cryogenic refrigeration module 212 may also be connected with cryogenic storage container 218, which may be configured to store large quantities of a cryogenic coolant, such as liquid nitrogen. Cryogenic refrigeration module 212 may include various control systems (e.g., Supervisory Control and Data Acquisition (SCADA)) that may be configured to control the distribution of liquid nitrogen from liquid nitrogen storage container 218 to each of HTS cables 202A, 202B, and 202C. This system may also be used to monitor the temperatures, flow rates and/or pressures of HTS cables 202A-C and each cryogenic refrigeration module as well as for numerous other cooling, heating, or pressurization functions.

Cryogenic refrigeration module 212 may include various commercially available cryogenic refrigeration systems. Such systems may include, but are not limited to, systems provided by Air Liquide of Paris, France and Praxair, Inc. of Danbury, Conn. Moreover, it should be noted that the cryogenic coolant used in the embodiments described herein is not limited to liquid nitrogen. Other suitable coolants may include, but are not limited to, natural gas, gaseous helium, hydrogen, liquified air, gas mixtures of oxygen and nitrogen in various percentages other than what occur in air, neon and mixtures of neon and nitrogen.

In some embodiments, HTS cables 202A, 202B, and 202C may be single phase cables, however, any other suitable HTS cable design may also be used. For example, and as described above, three groups of HTS layers separated by insulation layers may be utilized to carry three-phase power. An example of such a cable arrangement is the Triax HTS Cable arrangement described above. These cable arrangements may be employed as well.

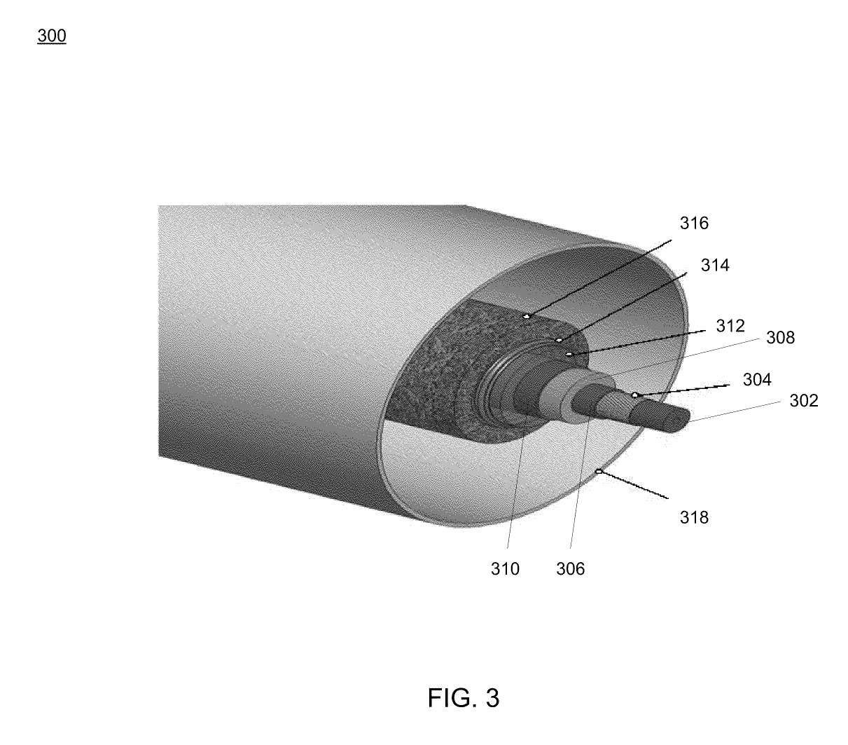

Referring now to FIG. 3, one exemplary embodiment of a single pole superconducting DC cable 300 is provided. In some embodiments, DC cable 300 may include interior member 302, around which may be wrapped and/or in contact with portions of coaxial cable assembly 304. Coaxial cable assembly 304 may be operatively connected with first inner layer 306 and may be composed of HTS materials, which along with second inner layer 310, may enclose layer 308. Layer 306 may be composed of conductive and/or semi-conductive materials to control electric field shapes. Layer 308 may be comprised of high voltage dielectric material which provides electrical insulation between layers 306 and 310 and which may have a graded composition which may also control electric field shape. Layer 310 may be comprised of high temperature superconducting, normal conducting, or semi-conductive materials which provide an outer electric current path and also control electric field shape. Second inner layer 310 and inner flexible sheath 314 may define a passageway 312 that may be configured to allow cryogenic fluid to pass through and also contain means to support inner layers. As discussed above, the cryogenic fluid may be liquid nitrogen or any other suitable cryogen. In one particular embodiment, the gap between second inner layer 310 and inner flexible sheath 314 may be approximately 19 mm. Inner flexible sheath 314 may have an inner diameter of approximately 127 mm, however, it should be noted that any mention of dimensions in the current specification is provided merely for exemplary purposes as numerous other dimensions, sizes, etc. may be used without departing from the scope of the present disclosure. Inner flexible sheath 314 is a vacuum and cryogen leakproof boundary and may be covered in one or more layers of thermal insulation, such as multi-layer insulation 316. DC cable 300 may be enclosed within rigid outer jacket possibly including anti-corrosion outer treatments 318 as is shown in FIG. 3. In one particular embodiment, rigid outer jacket 318 may have an outer diameter of approximately 460 mm.

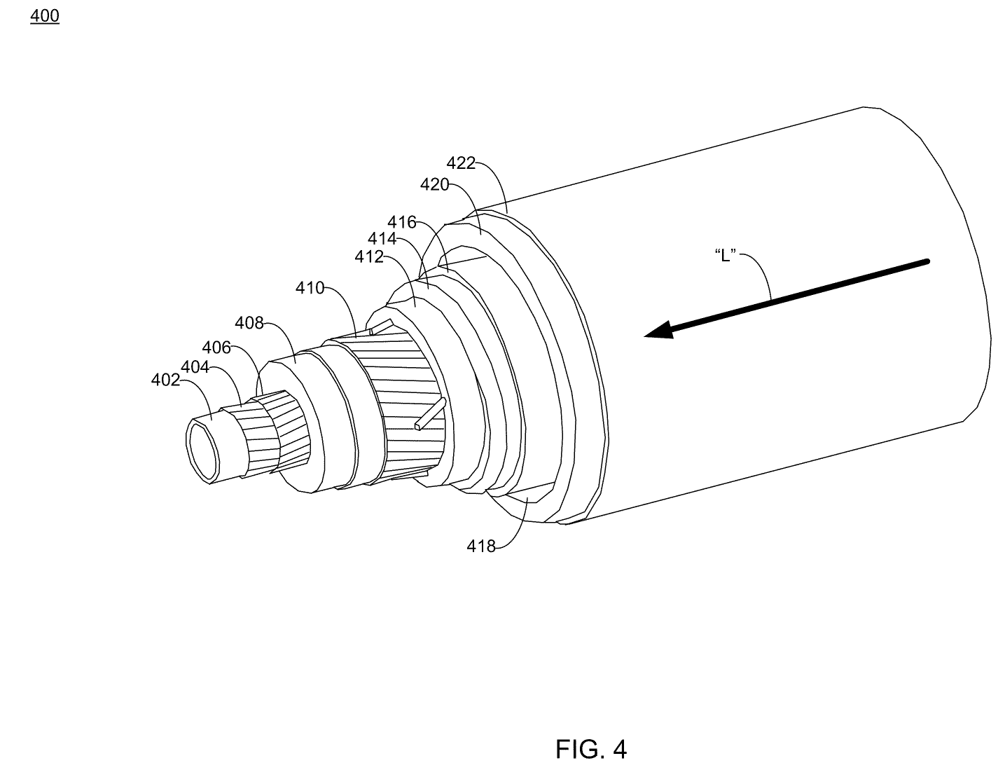

Referring now to FIG. 4, another embodiment depicting a flexible hollow-core DC cable 400 is shown. While HTS cable 400 may include various components of prior art copper-cored HTS cable, HTS cable 400 does not include a stranded copper core, which was replaced with a flexible hollow core (e.g., inner coolant passage 402). An example of inner coolant passage 402 may include, but is not limited to, a flexible, corrugated stainless steel tube. All copper shield layers are removed as well. A refrigerant (e.g., liquid nitrogen) may flow through inner coolant passage 402.

In a fashion similar to that of a copper-cored HTS cable, inner coolant passage 402 may be surrounded in radial succession by first HTS layer 404, second HTS layer 406 (usually helically wound with the opposite helicity of layer 404), high voltage dielectric insulation layer 408, HTS shield layer 410, coolant passage 412, inner cryostat wall 414, thermal insulation 416, vacuum space 418, outer cryostat wall 420 and an outer cable sheath 422. During operation, a refrigerant (e.g., liquid nitrogen, not shown) may be supplied from an external coolant source (not shown) and may be circulated within and along the length “L” of coolant passage 412 and inner coolant passage 402. An alternative coolant (e.g., liquid neon or liquid hydrogen) may be used in the case of lower transition temperature materials like MgB₂.

In some embodiments, any and/or all of the components of HTS cable 400 and/or 300 may be designed so as to enable flexibility continuously along the length of the cable. For example, inner coolant passage 402 (upon which first HTS layer 404 and second HTS layer 406 are wound) may be flexible. Accordingly, by utilizing flexible inner coolant passage 402, a flexible HTS cable 400 may be realized.

Examples of HTS cable 300 and/or 400 may include but are not limited to HTS cables available from Nexans of Paris France; Sumitomo Electric Industries, Ltd., of Osaka, Japan, Ultera (i.e., a joint venture of Southwire Company of Carrollton, Ga. and NKT cables of Cologne, Germany) and LS Cable of Korea. Additionally/alternatively, additional coaxial HTS and insulation layers may be utilized. For example, more than two layers of HTS wires may be used for a single phase. Also, three groups of HTS layers separated by insulation layers (not shown) may be utilized to carry three-phase power. An example of such a cable arrangement is the Triax HTS Cable arrangement proposed by Ultera (i.e., a joint venture of Southwire Company of Carrollton, Ga. and nkt cables of Cologne, Germany). Other embodiments of HTS cable 300 and/or 400 may include, but are not limited to: warm and/or cold dielectric configurations; single-phase vs. multi-phase configurations; and various shielding configurations (e.g., no shield and cryostat-based shielding). Additional details of HTS cable are described in U.S. patent application Ser. No. 11/459,167, issued Dec. 4, 2007 as U.S. Pat. No. 7,304,826 entitled Fault Management of HTS Power Cable and also in co-pending U.S. patent application Ser. No. 11/688,827, filed Mar. 20, 2007, entitled Parallel HTS Transformer Device.

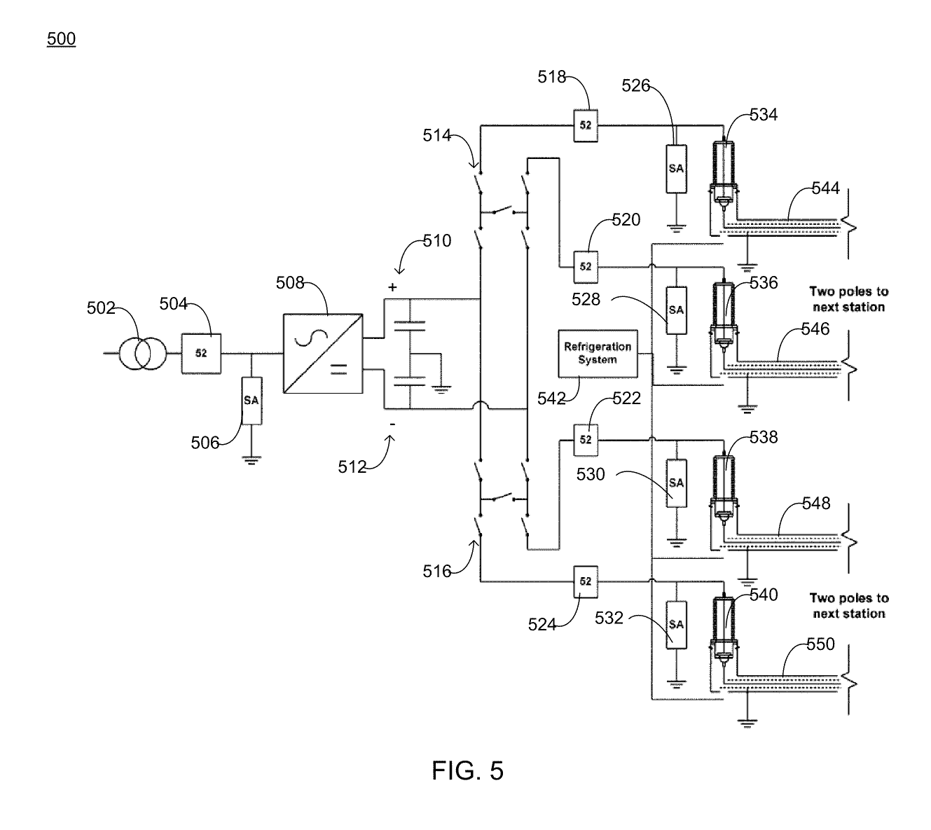

Referring now to FIG. 5, an exemplary embodiment of an electricity transmission system 500 is provided. System 500 may include electrical cross connections capable of adjusting the polarity of one or more DC cables, thus providing additional redundancy. System 500 may include a transformer 502 operatively connected to a circuit breaker 504. Transformer 502 may be of any suitable design, for example, in some embodiments, transformer 502 may be a step-down transformer, which may be configured to decrease the voltage and increase the current entering circuit breaker 504. Circuit breaker 504 may be a high-voltage circuit breaker configured to detect a fault condition and to interrupt the flow of electricity. Examples of circuit breakers may include, but are not limited to, those available from ABB, General Electric, AREVA, Mitsubishi Electric, Pennsylvania Breaker, Siemens, Toshiba, Kon\check{c}ar HVS, BHEL, etc.

In some embodiments, circuit breaker 504 may be operatively connected with AC/DC converter 508. A surge arrestor 506 may be placed between breaker 504 and converter 508. Surge arrestor 506 may include a high voltage terminal and a ground terminal and may be configured to protect parts of system 500 from a lightning strike. For example, when a lightning surge or switching surge travels down through parts of system 500 to arrester 506, the current from the surge may be diverted around the protected insulation in most cases to earth.

In some embodiments, AC/DC converter 508 may be configured to receive alternating current from one or more sections of the utility grid and to convert the current to DC for transmission along one or more superconducting DC cables. The output of AC/DC converter 508 may be provided to a positive polarity segment 510 and a negative polarity segment 512. Positive polarity segment 510 may operatively connect AC/DC converter 508 with first switching device 514. Similarly, negative polarity segment 512 may operatively connect AC/DC converter 508 with second switching device 516. In some embodiments, switching devices 514 and 516 may be configured as an H-bridge as shown in FIG. 5.

In some embodiments, first switching device 514 and second switching device 516 may be used to connect positive polarity segment 510 and/or negative polarity segment 512 with any or all of cable terminations 534, 536, 538, and/or 540. For example, first switching device 514 may provide one or more electrical pathways to cable termination 534. The electrical pathway may also include circuit breaker 518 and surge arrestor 526. Another electrical pathway is provided from first switching device 514 to cable termination 536. Similarly, this electrical pathway may also include circuit breaker 520 and surge arrestor 528. As shown in FIG. 5, first switching device 514 may also provide electrical pathways to cable terminations 538 and 540 via switching device 516. Second switching device 516 may also be configured to provide an electrical pathway to each of cable terminations 534, 536, 538, and/or 540 in a similar fashion. Circuit breaker 522 and surge arrestor 530 may be disposed along a pathway leading to cable termination 538 and circuit breaker 524 and surge arrestor 532 may be disposed along another pathway leading to cable termination 540. One or more refrigeration stations 542 may be operatively connected with each of DC superconducting cables 544, 546, 548, and/or 550. Refrigeration station 542 may be similar in operation and construction to those described above with reference to FIG. 2. A control system, not shown, may also be operatively connected to various portions of system 500. The control system may control the operation of each of the switching devices, and as a result, may be used to control the polarity along various cables throughout the system. The control system may be used to control and/or monitor the overall operation of numerous other components associated with system 500.

For example, and referring again to FIG. 1, each of switching devices 514 and 516 may be configured to operatively connect at least one of the first, second and third AC/DC converters 108, 110, and/or 112 with at least one of the pairs of superconducting DC cables. As shown in FIG. 5 and discussed in further detail hereinbelow, switching devices 514 and/or 516 may be further configured to adjust the polarity of one or more of superconducting DC cables, such as superconducting DC cables 102, 104, and/or 106 shown in FIG. 1 and/or superconducting DC cables 544, 546, 548, and/or 550 shown in FIG. 5.

In operation, the failure of any one segment of superconducting cable may be accommodated by taking that particular segment offline. The ring bus topology shown in FIG. 1 may provide a secondary path to each particular AC/DC converter. The failure of a second leg may also be accommodated provided it is of an opposite sign relative to the initial failed segment. If both failures occur in legs of the same sign or polarity, then operation may not continue. However, the configuration shown in FIG. 5 may allow for a segment to be reconnected to the opposite polarity at the terminal. System 500 may further include an interlocking device, which may be configured to prevent any unwanted or inadvertent pole to pole connections.

In addition to the ring configuration depicted in FIG. 1, the embodiments of the present disclosure may be expanded for use in long-distance point-to-point transfer of power. In this particular embodiment, a first AC/DC converter configured to receive a first alternating current having a first phase may be provided. A second AC/DC converter configured to receive a second alternating current having a second phase may also be provided. It is envisioned that these two converters may be located far away from one another, for example, first AC/DC converter may be located on the west coast of the United States and the second AC/DC converter may be located on the east coast. A first pair of superconducting DC cables may connect the first AC/DC converter and the second AC/DC converter and a second pair of superconducting DC cables may connect the first AC/DC converter and the second AC/DC converter. The first and second pair of superconducting DC cables may each include a first positive polarity cable and a first negative polarity cable. Superconducting DC cables may incur little to no voltage drop in the cables, which may allow for this long range transport of power. At least one switching device may be configured to operatively connect at least one of the first and second AC/DC converters with at least one of the pairs of superconducting DC cables, the switching device further configured to adjust the polarity of at least one of the polarity cables. In this way, the pairs of cables (e.g. 4 superconducting DC cables) may be arranged in a substantially parallel arrangement, here, linking the east and west coast, and may have one or more refrigeration units associated therewith, such as those described in FIGS. 5-8. In the event of a failure in any of the cable lengths, the embodiments described herein may be used to re-route the electricity and coolant, thus providing additional redundancy without incurring excessive additional costs.

Referring now to FIG. 6, one embodiment of a refrigeration unit 600 is provided. Refrigeration unit 600 may include cryogenic pump 602, heat exchangers 604 and 606, and cryogenic refrigerator 608. Refrigeration unit 600 may be operatively connected to one or more superconducting DC cables such as cables 102, 104, and/or 106 shown in FIG. 1 and/or cables 544, 546, 548, and/or 550 shown in FIG. 5.

In some embodiments, cryogenic pump 602 may be configured to supply pressurized subcooled cryogenic coolant, e.g., liquid nitrogen, through various legs of superconducting cable to one or more of heat exchangers 604 and 606. While FIG. 6 depicts a singular cryogenic pump 602 it should be noted that multiple pumps may be used without departing from the scope of the present disclosure. For example, multiple pumps may be configured in parallel to increase the power or for redundancy purposes. Pump 602 may be controlled via a control system (not shown), which may be configured to control the operation of pump 602, which may include controlling the number of pumps in use as well as providing flow control. The control system may also be used to control the numerous valves associated with refrigeration unit 600 in order to re-route the cryogenic fluid if one or more refrigeration unit is defective.

In some embodiments, heat exchangers 604 and 606 may be configured to absorb heat from one or more of the flows of cryogenic coolant. Although, two distinct heat exchangers are depicted in FIG. 6, it should be noted that any number of heat exchangers may be used without departing from the scope of the present disclosure. Heat exchangers 604 and 606 may also be operatively connected with cryogenic refrigerator 608. In some embodiments, cryogenic refrigerator 608 may include one or more gases, which may be cycled through various portions of unit 600 in order to establish and/or maintain the cryogenic coolant at a certain temperature. Cryogenic refrigerator 608 may be of any suitable design, including, for example, a Turbo-Brayton system.

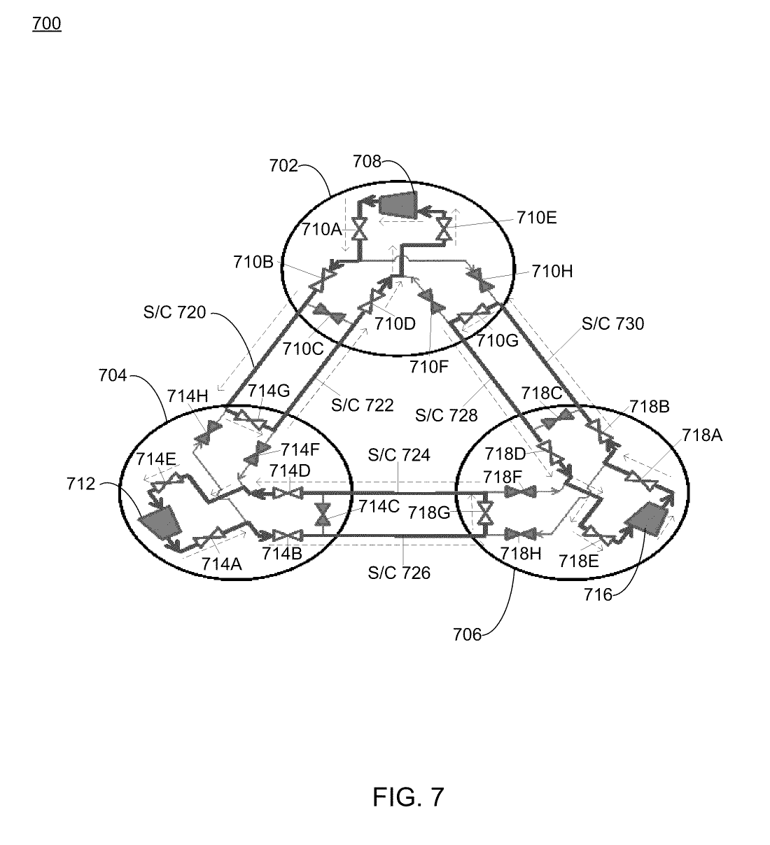

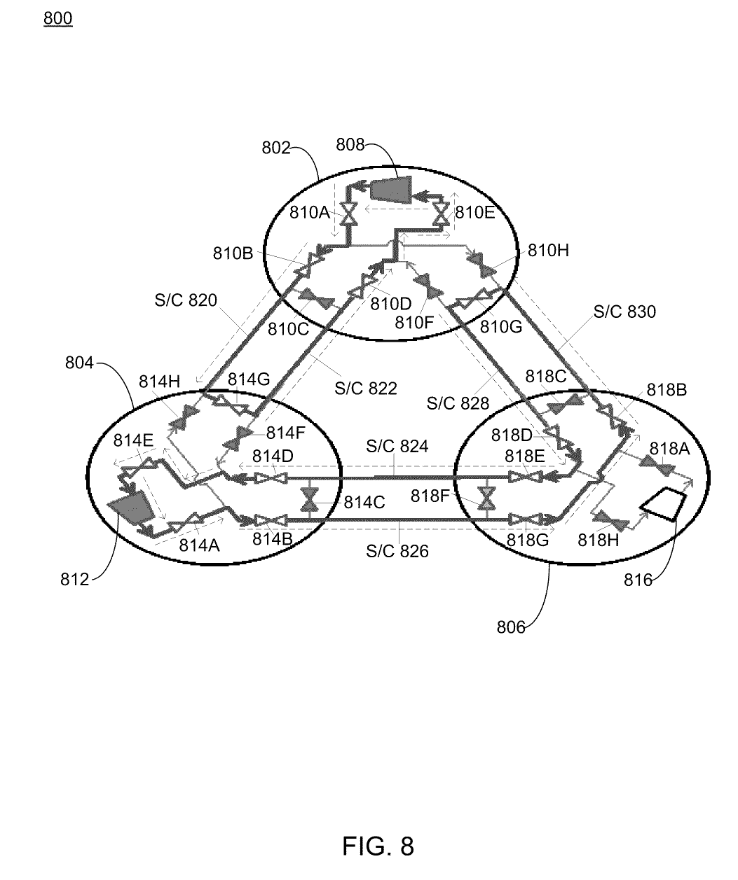

Referring now to FIGS. 7-8, exemplary embodiments of refrigeration systems 700 and 800 for use with HTS cable are shown. Refrigeration systems 700 and 800 may each include a plurality of refrigeration units. The refrigeration units shown in FIGS. 700 and 800 may be similar in configuration to those described in FIG. 6 and/or any of the embodiments described herein. Some of the components of the refrigeration units depicted in FIG. 6 have been omitted from FIGS. 7-8 for the sake of clarity.

FIG. 7 depicts an embodiment of refrigeration system 700 with all of the refrigeration units in full operation. System 700 may include first refrigeration unit 702 operatively connected with second refrigeration unit 704 and third refrigeration unit 706. Each refrigeration unit is operatively connected with at least one adjacent refrigeration unit via superconducting DC cables. For example, superconducting DC cables 720 and 722 may be used to link first refrigeration unit 702 and second refrigeration unit 704. Similarly, superconducting DC cables 724 and 726 may be used to link second refrigeration unit 704 and second refrigeration unit 706. Superconducting DC cables 728 and 730 may be used to link first refrigeration unit 702 and third refrigeration unit 706.

In operation, the direction of coolant through system 700 is indicated by the hashed arrow-tipped lines shown in FIG. 7, however, other configurations are also possible. Each refrigeration unit may include one or more valves, which may be configured to direct the flow of coolant through each refrigeration unit. For example, first refrigeration unit may include valves 710A-H, second refrigeration unit 704 may include valves 714A-H, and third refrigeration unit 706 may include valves 718A-H. Additional embodiments are also envisioned as the number and configuration of valves may be altered without departing from the scope of the present disclosure. FIG. 7 depicts a number of valves in a closed position, for example, valves 710C, 710F, and 710H in refrigeration unit 702, valves 714C, 714F, and 714H in refrigeration unit 704, and valves 718C, 718F, and 718H in refrigeration unit 706. A control system configured to control the flow of the cryogenic fluid through the superconducting DC cables, the control System 700 may further include a control system configured to allow for the re-routing of the cryogenic fluid through the superconducting DC cables. Re-routing of the cryogenic fluid may be necessary if a refrigeration unit or component associated therewith malfunction or becomes disabled. In this way, the control system may be configured to communicate with any of the components associated with system 700, e.g. to open and/or close individual valves, increase the flow of coolant, etc. One particular configuration for the re-routing of coolant throughout the electricity transmission system is shown in FIG. 8, which is described in further detail hereinbelow.

Referring now to FIG. 8, one exemplary embodiment of a refrigeration system 800 is shown. Refrigeration system 800 includes a malfunctioning coolant pump 816 in refrigeration unit 806. System 800 may be configured to identify a failure associated with one or more components in the system, in this example, pump 816. System 800 may include electrical circuitry and/or sensors, which may be in communication with the control system. As used in any embodiment described herein, “circuitry” may comprise, for example, singly or in any combination, hardwired circuitry, programmable circuitry, state machine circuitry, and/or firmware that stores instructions executed by programmable circuitry. It should be understood at the outset that any of the operations and/or operative components described in any embodiment herein may be implemented in software, firmware, hardwired circuitry and/or any combination thereof.

Once the failure has been identified, the control system may take certain components offline in order to re-route cryogenic coolant to the rest of system 800. In this embodiment, coolant pump 816 as well as valves 818A and 818H have been taken offline and the coolant has been redirected around pump 816. Again, as discussed in FIG. 7, the direction of coolant is indicated by the arrow-tipped hashed lines. As directed by the control system, valves 810C, 810F, and 810H in refrigeration unit 802, valves 814C, 814F, and 814H in refrigeration unit 804, and valves 818A, 818C, 818F, and 818H in refrigeration unit 806 have all been taken offline. The embodiment depicted in FIG. 8 is merely shown to indicate one possible reconfiguration of system 800 in the event of the failure of coolant pump 816, however, it should be noted that the present disclosure is capable of addressing failures in any of the components associated with system 800.

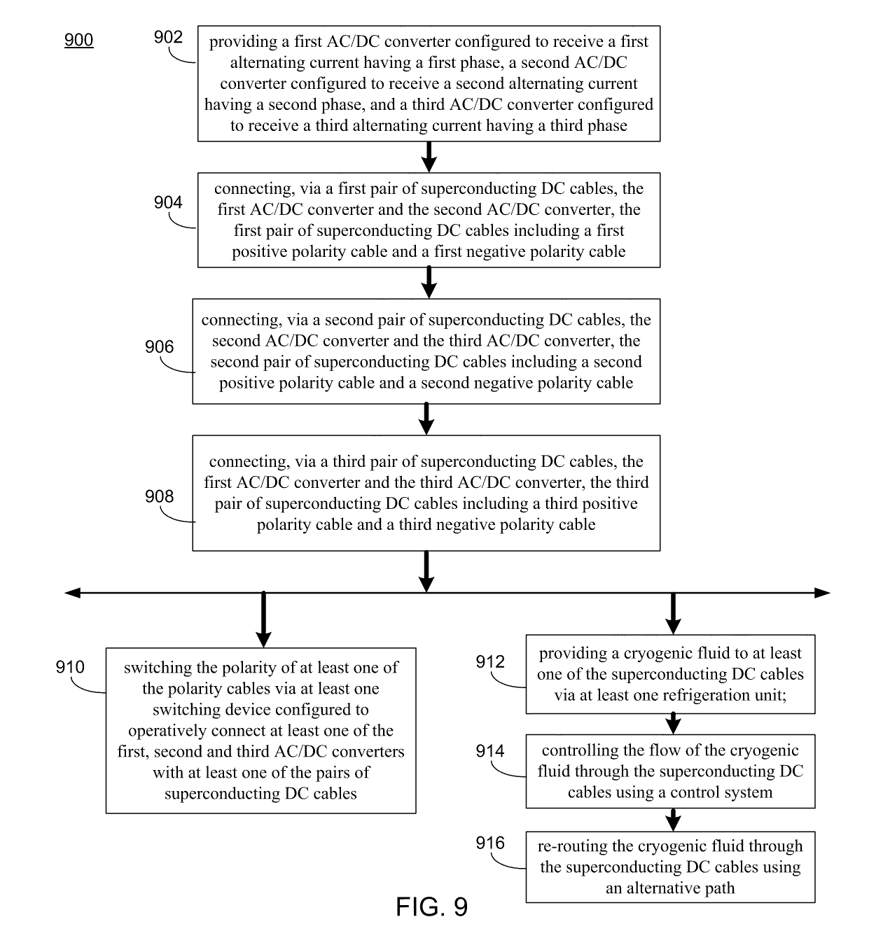

Referring now to FIG. 9, a flowchart 900 depicting operations in accordance with an exemplary embodiment of the present disclosure. Operations may include providing a first AC/DC converter configured to receive a first alternating current having a first phase, a second AC/DC converter configured to receive a second alternating current having a second phase, and a third AC/DC converter configured to receive a third alternating current having a third phase (902). The method may also include connecting, via a first pair of superconducting DC cables, the first AC/DC converter and the second AC/DC converter, the first pair of superconducting DC cables including a first positive polarity cable and a first negative polarity cable (904). The method may further include connecting, via a second pair of superconducting DC cables, the second AC/DC converter and the third AC/DC converter, the second pair of superconducting DC cables including a second positive polarity cable and a second negative polarity cable (906). The method may also include connecting, via a third pair of superconducting DC cables, the first AC/DC converter and the third AC/DC converter, the third pair of superconducting DC cables including a third positive polarity cable and a third negative polarity cable (908). The method may further include switching the polarity of at least one of the polarity cables via at least one switching device configured to operatively connect at least one of the first, second and third AC/DC converters with at least one of the pairs of superconducting DC cables (910). The method may additionally include providing a cryogenic fluid to at least one of the superconducting DC cables via at least one refrigeration unit (912), controlling the flow of the cryogenic fluid through the superconducting DC cables using a control system (914), and re-routing the cryogenic fluid through the superconducting DC cables using an alternative path (916).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

A number of implementations have been described. Nevertheless, it will be understood that various modifications may be made. Accordingly, other implementations are within the scope of the following claims.

What is claimed is:

1. A superconducting power grid comprising:
a first AC/DC converter configured to receive a first alternating current having a first phase;
a second AC/DC converter configured to receive a second alternating current having a second phase;
a third AC/DC converter configured to receive a third alternating current having a third phase;
a first pair of superconducting DC cables connecting the first AC/DC converter and the second AC/DC converter, the first pair of superconducting DC cables including a first positive polarity cable and a first negative polarity cable;
a second pair of superconducting DC cables connecting the second AC/DC converter and the third AC/DC converter, the second pair of superconducting DC cables including a second positive polarity cable and a second negative polarity cable;
a third pair of superconducting DC cables connecting the first AC/DC converter and the third AC/DC converter, the third pair of superconducting DC cables including a third positive polarity cable and a third negative polarity cable; and
at least one switching device configured to operatively connect at least one of the first, second and third AC/DC converters with at least one of the pairs of superconducting DC cables, the switching device further configured to adjust the polarity of at least one of the polarity cables.

2. The superconducting power grid of claim 1, wherein the switching device includes an H-bridge.

3. The superconducting power grid of claim 1, further comprising at least one refrigeration unit configured to provide a cryogenic fluid to at least one of the superconducting DC cables.

4. The superconducting power grid of claim 3, wherein the cryogenic fluid is liquid nitrogen.

5. The superconducting power grid of claim 4, further comprising at least one liquid nitrogen pump associated with the at least one refrigeration unit, the liquid nitrogen pump configured to alter a flow of liquid nitrogen through at least one of the superconducting DC cables.

6. The superconducting power grid of claim 5, further comprising a control system configured to re-route the cryogenic fluid if one or more of the at least one refrigeration unit is defective.

7. The superconducting power grid of claim 6, wherein the at least one refrigeration unit includes at least one heat exchanger operatively connected with a cryogenic refrigerator.

8. A superconducting power grid comprising:
a first AC/DC converter configured to receive a first alternating current having a first phase;
a second AC/DC converter configured to receive a second alternating current having a second phase;
a third AC/DC converter configured to receive a third alternating current having a third phase;
a first pair of superconducting DC cables connecting the first AC/DC converter and the second AC/DC converter, the first pair of superconducting DC cables including a first positive polarity cable and a first negative polarity cable;
a second pair of superconducting DC cables connecting the second AC/DC converter and the third AC/DC converter, the second pair of superconducting DC cables including a second positive polarity cable and a second negative polarity cable;
a third pair of superconducting DC cables connecting the first AC/DC converter and the third AC/DC converter, the third pair of superconducting DC cables including a third positive polarity cable and a third negative polarity cable;
at least one refrigeration unit configured to provide a cryogenic fluid to at least one of the superconducting DC cables; and
a control system configured to control the flow of the cryogenic fluid through the superconducting DC cables, the control system configured to allow for the re-routing of the cryogenic fluid through the superconducting DC cables.

9. The superconducting power grid of claim 8, wherein the control system is configured to re-route the cryogenic fluid if a refrigeration unit associated with any of the AC/DC converters is disabled.

10. The superconducting power grid of claim 8, wherein each of the superconducting DC cables includes at least one high temperature superconducting (HTS) wire.

11. The superconducting power grid of claim 8, wherein each of the superconducting DC cables includes a conduit configured to contain the cryogenic fluid.

12. The superconducting power grid of claim 8, wherein at least two of the first phase, second phase and third phases are different.

13. A method for providing redundancy in a superconducting power grid comprising:
providing a first AC/DC converter configured to receive a first alternating current having a first phase, a second AC/DC converter configured to receive a second alternating current having a second phase, and a third AC/DC converter configured to receive a third alternating current having a third phase;
connecting, via a first pair of superconducting DC cables, the first AC/DC converter and the second AC/DC converter, the first pair of superconducting DC cables including a first positive polarity cable and a first negative polarity cable;
connecting, via a second pair of superconducting DC cables, the second AC/DC converter and the third AC/DC converter, the second pair of superconducting DC cables including a second positive polarity cable and a second negative polarity cable;
connecting, via a third pair of superconducting DC cables, the first AC/DC converter and the third AC/DC converter, the third pair of superconducting DC cables including a third positive polarity cable and a third negative polarity cable; and
switching the polarity of at least one of the polarity cables via at least one switching device configured to operatively connect at least one of the first, second and third AC/DC converters with at least one of the pairs of superconducting DC cables.

14. A method for providing redundancy in a superconducting power grid comprising:
providing a first AC/DC converter configured to receive a first alternating current having a first phase, a second AC/DC converter configured to receive a second alternating current having a second phase, and a third AC/DC converter configured to receive a third alternating current having a third phase;
connecting, via a first pair of superconducting DC cables, the first AC/DC converter and the second AC/DC converter, the first pair of superconducting DC cables including a first positive polarity cable and a first negative polarity cable;
connecting, via a second pair of superconducting DC cables, the second AC/DC converter and the third AC/DC converter, the second pair of superconducting DC cables including a second positive polarity cable and a second negative polarity cable;
connecting, via a third pair of superconducting DC cables, the first AC/DC converter and the third AC/DC converter, the third pair of superconducting DC cables including a third positive polarity cable and a third negative polarity cable;
providing a cryogenic fluid to at least one of the superconducting DC cables via at least one refrigeration unit;
controlling the flow of the cryogenic fluid through the superconducting DC cables using a control system; and
re-routing the cryogenic fluid through the superconducting DC cables using an alternate path.

15. A superconducting power grid comprising:
a first AC/DC converter configured to receive a first alternating current having a first phase;
a second AC/DC converter configured to receive a second alternating current having a second phase;
a first pair of superconducting DC cables connecting the first AC/DC converter and the second AC/DC converter, the first pair of superconducting DC cables including a first positive polarity cable and a first negative polarity cable;
a second pair of superconducting DC cables connecting the first AC/DC converter and the second AC/DC converter, the second pair of superconducting DC cables including a second positive polarity cable and a second negative polarity cable; and
at least one switching device configured to operatively connect at least one of the first and second AC/DC converters with at least one of the pairs of superconducting DC cables, the switching device further configured to adjust the polarity of at least one of the polarity cables.

16. The superconducting power grid of claim 15, further comprising at least one refrigeration unit associated with one or more of the superconducting cables.

17. The superconducting power grid of claim 16, wherein the at least one refrigeration unit is configured to provide a cryogenic fluid to the one or more superconducting cables.

18. The superconducting power grid of claim 17, further comprising a control system configured to control the flow of the cryogenic fluid through the superconducting DC cables, the control system configured to allow for the re-routing of the cryogenic fluid through the superconducting DC cables.

19. The superconducting power grid of claim 15, wherein the at least one switching device is an H-bridge.

20. The superconducting power grid of claim 18, wherein the control system redirects the flow of coolant if one or more of the at least one refrigeration units is disabled.
